(19) United States
(12) Patent Application Publication
(10) Pub. No.: US 2009/0061593 A1
(43) Pub. Date: Mar. 5, 2009

(54) Semiconductor Wafer Re-Use in an Exfoliation Process Using Heat Treatment

(76) Inventors: Kishor Purushottam Gadkaree, Big Flats, NY (US); Mark Andrew Stocker, Market Harborough (GB)

Correspondence Address: CORNING INCORPORATED, SP-TI-3-1, CORNING, NY, 14831, US

(21) Appl. No.: 12/170,797

(22) Filed: Jul. 10, 2008

Related U.S. Application Data
(60) Provisional application No. 60/966,439, filed on Aug. 28, 2007.

(51) Int. Cl. H01L 21/30; B32B 17/06

(52) U.S. Cl. 438/458; 428/426; 257/E21.211

(57) ABSTRACT

Methods and apparatus for re-using a semiconductor donor wafer in a semiconductor-on-insulator (SOI) fabrication process provide for: (a) subjecting a first implantation surface of a donor semiconductor wafer to an ion implantation process to create a first exfoliation layer of the donor semiconductor wafer; (b) bonding the first implantation surface of the first exfoliation layer to a first insulator substrate; (c) separating the first exfoliation layer from the donor semiconductor wafer, thereby exposing a first cleaved surface of the donor semiconductor wafer, the first cleaved surface having a first damage thickness; and (d) subjecting the first cleaved surface of the donor semiconductor wafer to one or more elevated temperatures over time to reduce the first damage thickness to a sufficient level to produce a second implantation surface.

### CROSS REFERENCE TO RELATED APPLICATIONS

This application claims the benefit of U.S. Provisional Patent Application No.: 60/966,439, filed Aug. 28, 2007, the entire disclosure of which is hereby incorporated by reference.

### BACKGROUND

The present invention relates to the manufacture of semiconductor-on-insulator (SOI) structures using an improved process for making same.

To date, the semiconductor material most commonly used in semiconductor-on-insulator structures has been silicon. Such structures have been referred to in the literature as silicon-on-insulator structures and the abbreviation “SOI” has been applied to such structures. SOI technology is becoming increasingly important for high performance thin film transistors, solar cells, and displays, such as, active matrix displays. SOI structures may include a thin layer of substantially single crystal silicon (generally 0.1-0.3 microns in thickness but, in some cases, as thick as 5 microns) on an insulating material. The state of the art processes for forming TFTs on polysilicon result in silicon thicknesses on the order of about 50 nm. Among the limiting factors on the performance of the silicon in a polysilicon TFT is existence of grain boundaries in the silicon structure.

For ease of presentation, the following discussion will at times be in terms of SOI structures. The references to this particular type of SOI structure are made to facilitate the explanation of the invention and are not intended to, and should not be interpreted as, limiting the invention's scope in any way. The SOI abbreviation is used herein to refer to semiconductor-on-insulator structures in general, including, but not limited to, silicon-on-insulator structures. Similarly, the SiOG abbreviation is used to refer to semiconductor-on-glass structures in general, including, but not limited to, silicon-on-glass structures. The SiOG nomenclature is also intended to include semiconductor-on-glass-ceramic structures, including, but not limited to, silicon-on-glass-ceramic structures. The abbreviation SOI encompasses SiOG structures.

Various ways of obtaining SOI structures wafer include epitaxial growth of silicon (Si) on lattice matched substrates. An alternative process includes the bonding of a single crystal silicon wafer to another silicon wafer on which an oxide layer of SiO₂ has been grown, followed by polishing or etching of the top wafer down to, for example, a 0.05 to 0.3 micron layer of single crystal silicon. Further methods include ion-implantation methods in which either hydrogen or oxygen ions are implanted either to form a buried oxide layer in the silicon wafer topped by Si in the case of oxygen ion implantation or to separate (exfoliate) a thin Si layer to bond to another Si wafer with an oxide layer as in the case of hydrogen ion implantation.

The former two methods have not resulted in satisfactory structures in terms of cost and/or bond strength and durability. The latter method involving hydrogen ion implantation has received some attention and has been considered advantageous over the former methods because the implantation energies required are less than 50% of that of oxygen ion implants and the dosage required is two orders of magnitude lower.

U.S. Pat. No. 5,374,564 discloses a process to obtain a single crystal silicon film on a substrate using a thermal process. A silicon wafer having a planar face is subject to the following steps: (i) implantation by bombardment of a face of the silicon wafer by means of ions creating a layer of gaseous micro-bubbles defining a lower region of the silicon wafer and an upper region constituting a thin silicon film; (ii) contacting the planar face of the silicon wafer with a rigid material layer (such as an insulating oxide material); and (iii) a third stage of heat treating the assembly of the silicon wafer and the insulating material at a temperature above that at which the ion bombardment was carried out. The third stage employs temperatures sufficient to bond the thin silicon film and the insulating material together, to create a pressure effect in the micro-bubbles, and to cause a separation between the thin silicon film and the remaining mass of the silicon wafer. (Due to the high temperature steps, this process does not work with lower cost glass or glass-ceramic substrates.)

U.S. Pat. No. 7,176,528 discloses a process that produces an SiOG structure. The steps include: (i) exposing a silicon wafer surface to hydrogen ion implantation to create a bonding surface; (ii) bringing the bonding surface of the wafer into contact with a glass substrate; (iii) applying pressure, temperature and voltage to the wafer and the glass substrate to facilitate bonding therebetween; and (iv) cooling the structure to a common temperature to facilitate separation of the glass substrate and a thin layer of silicon from the silicon wafer.

After the removal of a first thin layer of silicon (or other semiconductor material) from the donor semiconductor wafer in the SOI process, which may remove only about one micron, about 95% or more of the donor semiconductor wafer may still be available for further use. The re-use of a donor semiconductor wafer has a relatively significant impact on the cost to produce an SOI structure, particularly a large area SOI structure. Donor semiconductor wafer re-use—which may be a dominant factor impacting the process cost—defines how many times a given donor semiconductor wafer can be used during numerous bonding processes to produce SOI structure(s). The re-use factor is even more important when a large area SOI is being produced using separate semiconductor layer structures laterally disposed over a given glass substrate (so-called tiling). For such processes, it is desirable to re-use a given donor semiconductor wafer as many times as possible.

For re-use it is necessary to return a bonding surface of the donor semiconductor wafer to a relatively damage-free state. Conventionally, this is done by removing a certain thickness of the donor semiconductor wafer which is damaged due to the exfoliation (separation) process. This may be done via standard polishing techniques, such as chemical mechanical polishing (CMP). Polishing, however, is expensive. In addition, polishing can result in subsurface damage, non-uniform material removal, as well as the loss of significant amounts of material. Polishing processes and the accompanying pre-polish and post-polish cleaning processes are quite aggressive, often resulting in premature wafer breakage.

The conventional polishing processes, such as CMP, do not remove material uniformly across the surface of the donor semiconductor wafer. The state of the art for round semiconductor wafer surface non-uniformities (standard deviation/mean removal thickness) is typically 5-10% of the material thickness removed. As more of the semiconductor material is removed, the variation in the thickness correspondingly worsens. Another problem with the CMP process is that it exhibits particularly poor results when rectangular SOI structures (e.g., those having sharp corners) are polished. Indeed, the aforementioned surface non-uniformities are amplified at the corners of the SOI structure compared with those at the center thereof. Multiple re-use of the donor semiconductor wafer by polishing will result in the premature end to a given wafer's re-use cycle life when the surface geometry (e.g., near the corners if rectangular) exceeds re-use functional limits.

Due to the non-uniformities in the conventional polishing arts, if for example 0.150 microns of actual damage needs to be removed from the bonding surface of the donor semiconductor wafer, then to be certain that the damage layer has been completely removed over the whole surface, at least 1.0 micron may be the target thickness for removal. Thus over five times the thickness of the actual damage is removed in order to be sure that all the damage is removed. This is highly wasteful and has significant, negative cost implications.

Still further, the polishing process introduces aggressive slurries (chemicals and abrasive particles) onto the bonding surface of the donor semiconductor wafer. These chemicals and particles have to be removed from the bonding surface before they dry and become permanently adhered to the bonding surface. This is a very expensive process and adds significantly to the overall polishing process cost.

### SUMMARY

In accordance with one or more embodiments of the present invention, methods and apparatus for re-using a semiconductor donor wafer in a semiconductor-on-insulator (SOI) fabrication process provide for: (a) subjecting a first implantation surface of a donor semiconductor wafer to an ion implantation process to create a first exfoliation layer of the donor semiconductor wafer; (b) bonding the first implantation surface of the first exfoliation layer to a first insulator substrate; (c) separating the first exfoliation layer from the donor semiconductor wafer, thereby exposing a first cleaved surface of the donor semiconductor wafer, the first cleaved surface having a first damage thickness; and (d) subjecting the first cleaved surface of the donor semiconductor wafer to one or more elevated temperatures over time to reduce the first damage thickness to a sufficient level to produce a second implantation surface.

The methods and apparatus may further include repeating steps (a)-(d) to produce further exfoliation layers for further SOI structures. The one or more elevated temperatures may include at least one temperature within the range of about 700 degrees C to about 1200 degrees C, with about 1000-1100 degrees C being preferred. The annealing time may be between about 1 to about 8 hours, such as about 4 hours (e.g., at 1000 degrees C).

The step of subjecting the first cleaved surface of the donor semiconductor wafer to one or more elevated temperatures over time may be conducted in an inert atmosphere, such as an argon gas or other suitable inert gas. Alternatively, the atmosphere may be a reducing atmosphere, such as including hydrogen (or other reducing gas), or a mixture of an inert gas and a reducing gas.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a simplified side view illustrating the structure of an SOG device in accordance with one or more embodiments of the present invention;

FIG. 2 is a simplified diagram illustrating the re-use of a donor semiconductor wafer used to form a number of the SOG devices of FIG. 1 in accordance with one or more embodiments of the present invention;

FIGS. 3-6 are simplified schematic diagrams illustrating intermediate structures formed using processes of the present invention to produce the SOG device of FIG. 1;

FIG. 7 is a side view illustrating the donor semiconductor wafer just following the exfoliation of a thin layer therefrom to form the structure of FIG. 5;

FIG. 8 is a schematic diagram illustrating a thermal treatment process for conditioning the bonding surface of the donor semiconductor wafer to prepare same for a subsequent bonding and exfoliation procedure; and

FIGS. 9-10 are graphs illustrating the surface roughness characteristics of the bonding surface of the donor semiconductor wafer pre- and post-thermal treatment, respectively.

### DETAILED DESCRIPTION

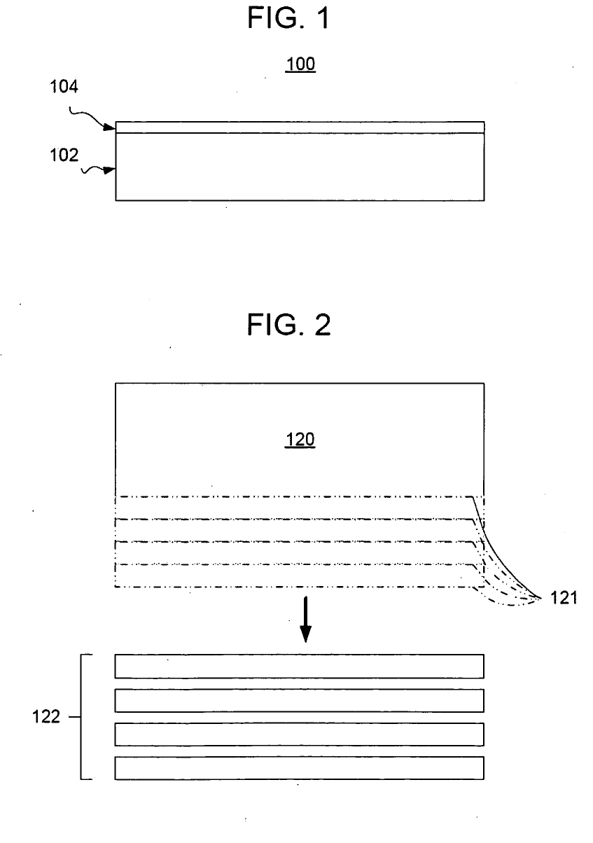

With reference to the drawings, wherein like numerals indicate like elements, there is shown in FIG. 1 an SOI structure (in particular, an SOG structure) 100 in accordance with one or more embodiments of the present invention. The SOG structure 100 includes an insulator substrate, such as a glass or glass ceramic substrate 102, and a semiconductor layer 104. The SOG structure 100 has application for use in displays, including organic light-emitting diode (OLED) displays and liquid crystal displays (LCDs), integrated circuits, photovoltaic devices, thin film transistor applications, etc.

The semiconductor material of the layer 104 may be in the form of a substantially single-crystal material. The term “substantially” is used in describing the layer 104 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material.

For the purposes of discussion, it is assumed that the semiconductor layer 104 is formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, and InP.

With reference to FIG. 2, it is desirable to form many such SOG structures 100 in a manufacturing process, either for separate products, or for an integrated device in which multiple SOG structures are needed. In either case, one way to produce multiple SOG structures 100 is to cleave (or exfoliate) a thin exfoliation layer 122 of semiconductor material from a donor semiconductor wafer 120 during a process in which the exfoliation layer 122 is bonded to the glass substrate 102. After the removal of a first exfoliation layer 122 of semiconductor material from the donor semiconductor wafer 120, a significant amount of the donor semiconductor wafer 120 (possibly 95% or more) is still available for further use. The re-use of a donor semiconductor wafer 120 has a relatively significant impact on the cost to produce a number of SOG structures 100, particularly large area SOG structures. As will be discussed in more detail later herein, it is necessary to return a bonding surface 121 (or cleaved surface) of the donor semiconductor wafer 120 to a relatively damage-free state for a subsequent bonding process. The specific techniques used to process the cleaved surface 121 and make it ready for bonding may also have a significant impact on the overall cost to produce the SOG structures 100. These techniques will be described in more detail later herein.

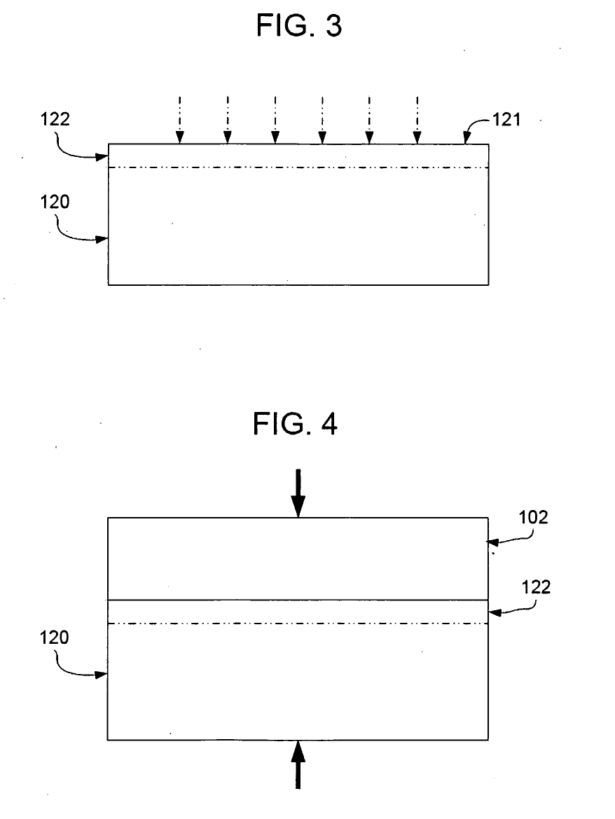

Reference is now made to FIGS. 3-6, which illustrate intermediate structures that may be formed in order to produce the SOG structure 100. Turning first to FIG. 3, an implantation surface 121 of a donor semiconductor wafer 120 is prepared, such as by polishing, cleaning, etc. to produce a relatively flat and uniform implantation surface 121 suitable for bonding to the glass or glass-ceramic substrate 102. For the purposes of discussion, the semiconductor wafer 120 may be a substantially single crystal silicon wafer, although as discussed above any other suitable semiconductor conductor material may be employed.

An exfoliation layer 122 is created by subjecting the implantation surface 121 to one or more ion implantation processes to create a weakened region below the implantation surface 121 of the donor semiconductor wafer 120. Although the embodiments of the present invention are not limited to any particular method of forming the exfoliation layer 122, one suitable method dictates that the implantation surface 121 of the donor semiconductor wafer 120 may be subject to a hydrogen ion implantation process to at least initiate the creation of the exfoliation layer 122 in the donor semiconductor wafer 120. The implantation energy may be adjusted using conventional techniques to achieve a general thickness of the exfoliation layer 122, such as between about 300-500 nm. By way of example, hydrogen ion implantation may be employed, although other ions or multiples thereof may be employed, such as boron+hydrogen, helium+hydrogen, or other ions known in the literature for exfoliation. Again, any other known or hereinafter developed technique suitable for forming the exfoliation layer 122 may be employed without departing from the spirit and scope of the present invention.

The donor semiconductor wafer 120 may be treated to reduce, for example, the hydrogen ion concentration on the implantation surface 121. For example, the donor semiconductor wafer 120 may be washed and cleaned and the implantation donor surface 121 of the exfoliation layer 122 may be subject to mild oxidation. The mild oxidation treatments may include treatment in oxygen plasma, ozone treatments, treatment with hydrogen peroxide, hydrogen peroxide and ammonia, hydrogen peroxide and an acid or a combination of these processes. It is expected that during these treatments hydrogen terminated surface groups oxidize to hydroxyl groups, which in turn also makes the surface of the silicon wafer hydrophilic. The treatment may be carried out at room temperature for the oxygen plasma and at temperature between 25-150° C. for the ammonia or acid treatments.

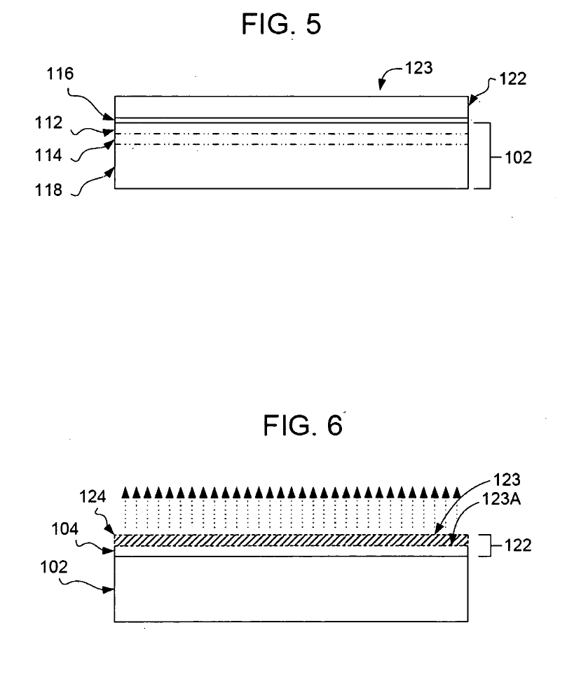

With reference to FIGS. 4-5 the glass substrate 102 may be bonded to the exfoliation layer 122 using an electrolysis process. A suitable electrolysis bonding process is described in U.S. Pat. No. 7,176,528, the entire disclosure of which is hereby incorporated by reference. Portions of this process are discussed below. In the bonding process, appropriate surface cleaning of the glass substrate 102 (and the exfoliation layer 122 if not done already) may be carried out. Thereafter, the intermediate structures are brought into direct or indirect contact to achieve the arrangement schematically illustrated in FIG. 4. Prior to or after the contact, the structure(s) comprising the donor semiconductor wafer 120, the exfoliation layer 122, and the glass substrate 102 are heated under a differential temperature gradient. The glass substrate 102 may be heated to a higher temperature than the donor semiconductor wafer 120 and exfoliation layer 122. By way of example, the temperature difference between the glass substrate 102 and the donor semiconductor wafer 120 (and the exfoliation later 122) is at least 1 degree C, although the difference may be as high as about 100 to about 150 degrees C. This temperature differential is desirable for a glass having a coefficient of thermal expansion (CTE) matched to that of the donor semiconductor wafer 120 (such as matched to the CTE of silicon) since it facilitates later separation of the exfoliation layer 122 from the semiconductor wafer 120 due to thermal stresses.

Once the temperature differential between the glass substrate 102 and the donor semiconductor wafer 120 is stabilized, mechanical pressure is applied to the intermediate assembly. The pressure range may be between about 1 to about 50 psi. Application of higher pressures, e.g., pressures above 100 psi, might cause breakage of the glass substrate 102.

The glass substrate 102 and the donor semiconductor wafer 120 may be taken to a temperature within about ±150 degrees C of the strain point of the glass substrate 102.

Next, a voltage is applied across the intermediate assembly, for example with the donor semiconductor wafer 120 at the positive electrode and the glass substrate 102 the negative electrode. The intermediate assembly is held under the above conditions for some time (e.g., approximately 1 hour or less), the voltage is removed and the intermediate assembly is allowed to cool to room temperature.

With reference to FIG. 5, prior to, during and/or after cooling the donor semiconductor wafer 120 and the glass substrate 102 are separated, which may include some peeling if they have not already become completely free, to obtain a glass substrate 102 with the relatively thin exfoliation layer 122 formed of the semiconductor material of the donor semiconductor layer 120 bonded thereto. The separation may be accomplished via fracture of the exfoliation layer 122 due to thermal stresses. Alternatively or in addition, mechanical stresses such as water jet cutting or chemical etching may be used to facilitate the separation.

The separation of the donor semiconductor wafer 120 and the glass substrate 102 is accomplished through application of stress to the implantation zone, such as by a heating and/or cooling process. It is noted that the characteristics of the heating and/or cooling process may be established as a function of a strain point of the glass substrate 102. Although the invention is not limited by any particular theory of operation, it is believed that glass substrates 102 with relatively low strain points may facilitate separation when the respective temperatures of the donor semiconductor wafer 120 and the glass substrate 102 are falling or have fallen during cooling. Similarly, it is believed that glass substrates 102 with relatively high strain points may facilitate separation when the respective temperatures of the donor semiconductor wafer 120 and the glass substrate 102 are rising or have risen during heating. Thus, in accordance with one or more aspects of the present invention, separation donor semiconductor wafer 120 and the glass substrate 102 may include one of: cooling the donor semiconductor wafer 120 and the glass substrate 102 such that separation occurs when respective temperatures thereof are falling; heating the donor semiconductor wafer 120 and the glass substrate 102 such that separation occurs when the respective temperatures thereof are rising); and achieving separation of the donor semiconductor wafer 120 and the glass substrate 102 when respective temperatures thereof are neither substantially rising nor falling (e.g., at some steady state or dwell situation), during cooling or heating.

With reference to FIG. 6, the cleaved surface 123 of the exfoliation layer 122 just after separation may exhibit excessive surface roughness, excessive silicon layer thickness, and implantation damage of the silicon layer (e.g., due to the formation of an amorphized silicon layer). In some cases, the amorphized silicon layer may be on the order of about 50-150 nm in thickness. In addition, depending on the implantation energy and implantation time, the thickness of the exfoliation layer 122 may be on the order of about 300-500 nm. The final thickness of the semiconductor layer 104 should be between about 10-250 nm. Accordingly, the cleaved surface 123 is subject to post processing, which may include subjecting the cleaved surface 123 to a polishing, etching, or other process, indicated by the arrows showing removal of material. The post process is intended to remove material 124 of the exfoliation layer 122, leaving the semiconductor layer 104.

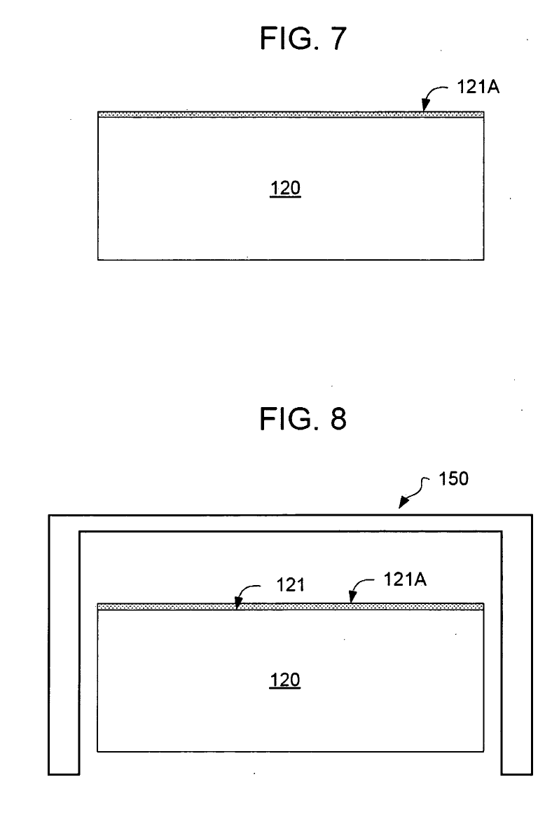

With reference to FIG. 7, the cleaved surface 121A of the donor semiconductor wafer 120 may also exhibit excessive surface roughness and implantation damage—the thickness of the damage zone may be 200 nm or more. In accordance with one or more aspects of the present invention, the cleaved surface 121A of the donor semiconductor wafer 120 is subject to one or more elevated temperatures over time (annealed) to reduce the damage to a sufficient level to produce a further implantation surface 121 (FIG. 3) suitable for producing a further SOG structure 100. It is contemplated that the steps of creating an exfoliation layer 122, bonding the exfoliation layer 122 to a substrate 102, separating the exfoliation layer 122, and subsequent heat treatment—to repair the surface 121A of the donor semiconductor wafer 120—are repeated numerous times to utilize significant portions of the donor semiconductor wafer 120 (FIG. 2), thereby reducing processing costs.

Conventional polishing to produce a bonding compatible surface texture and remove the damage layer requires excessive material removal in order to guarantee that all damage has been removed. The use of a thermal healing process in accordance with the present invention has another advantage. When thermal heat treatment is used to reduce or eliminate the damage layer, a very shallow polishing depth (say 10 nm) can be used in order to prepare the surface texture making it compatible with the bonding process. A simple non destructive test can be used to determine whether the full surface texture has been sufficiently removed enabling the simple development of an optimal material removal process. For example, additional touch polishing or Kiss polishing on the annealed surface may be carried out to remove any remaining rough spots. The touch polishing process includes removal of a small amount of material, such as between about 10-100 nm, as opposed to removal of about 1000 nm of material in standard polishing. Coupling a shallow polishing process with a thermal healing process also enables the removal of un-exfoliated spots that cannot be removed by thermal or chemical processes alone.

With reference to FIG. 8, in order to accomplish the heat treatment (annealing) process, the donor semiconductor wafer 120 may be placed into a temperature chamber 150. The cleaved surface 121A may then be subject to one or more elevated temperatures over time to reduce the damage (e.g., reduce the thickness of the damage zone thereof) to a sufficient level to achieve another implantation surface 121. The elevated temperatures may include at least one temperature within the range of about 700 degrees C to about 1200 degrees C. A preferred temperature is about 1000-1000C degrees C. The time duration over which the heat treatment is applied may be between about 1 to about 8 hours, with about 4 hours being preferred. The atmosphere within the chamber 150 may be an inert atmosphere or a reducing atmosphere. The inert atmosphere may include argon, or another suitable inert gas. When a reducing atmosphere is employed, the atmosphere may include hydrogen, or may be a mixture of argon (or other inert gas) plus hydrogen.

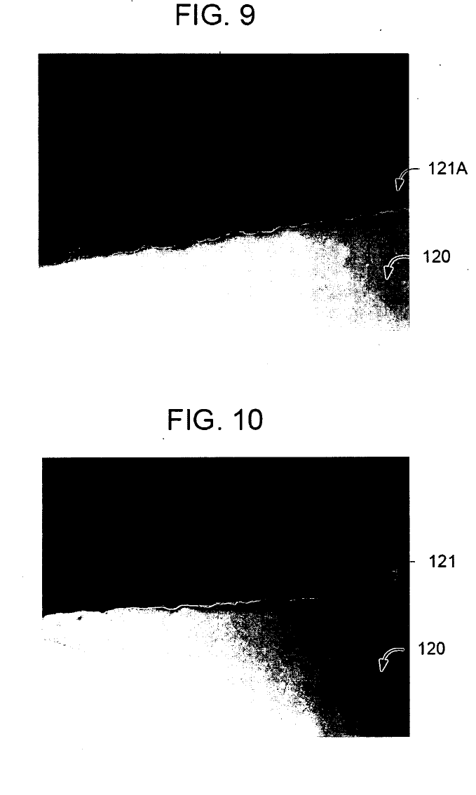

In an experiment, a silicon donor wafer of 100 mm diameter and 100 microns thickness was hydrogen ion implanted at dosage of 8×10*16 ions/cm2 and an implantation energy of 100 KeV. The silicon donor wafer was then treated in oxygen plasma to oxidize the surface groups thereof. An EAGLE 2000® glass wafer of 100 mm diameter was: (i) washed with Fischer scientific Contrad 70 detergent in ultrasonic bath for 15 minutes; (ii) washed in distilled water for 15 minutes in an ultrasonic bath; (iii) washed in 10% nitric acid; and (iv) washed in distilled water. The silicon donor wafer and the glass wafer were cleaned in a spin washer—dryer with distilled water in a clean room environment. The silicon donor wafer and the glass wafer were placed in a Suss Microtech bonder. The glass wafer was placed on the negative electrode and the silicon donor wafer was placed on the positive electrode, where the silicon donor wafer was held away from the glass wafer with spacers. The silicon donor wafer was heated to 525 degrees C, while the glass wafer was heated to 575 degrees C in a nitrogen atmosphere. The wafers were then brought into contact with one another. A potential of 1750 Volts was applied across the wafer surfaces for 20 minutes. The wafers were then cooled to room temperature. The wafers separated easily. A strongly adhered thin silicon film (of about 500 nm) was bonded to the glass substrate. With reference to FIG. 9, the silicon donor wafer 120 was examined via TEM. The damaged surface 121A exhibited a thickness of about 200 nm.

With reference to FIG. 10, the silicon donor wafer was heat treated at 1000 degrees C for four hours in an argon atmosphere. The surface 121 of the silicon donor wafer 120 was then examined via TEM, and the result was that the damage had been substantially healed. The silicon donor wafer 120 was hydrogen ion implanted again and the silicon film transfer process was repeated. The result was the production of another strongly adhered thin silicon film (of about 500 nm) bonded to a glass substrate. Additionally, touch polishing may be performance to reduce surface roughness. The heat treatment process reduces and/or eliminates the damage in the silicon donor wafer 120, while the touch polishing removes surface roughness.

In accordance with a paper by J. L. Vasal et al., “A Novel Method For Achieving Very Low Cops In CZ Wafers”, MEMC Electronic Materials Inc., (publication status unknown), the sequential healing of silicon wafers to remove damage and improve surface texture may be achieved using first a hydrogen atmosphere, and second an argon atmosphere—in order to produce a less jagged surface texture. In accordance with one or more further aspects of the present invention, the process of ion hydrogen implantation may leave existing hydrogen on the damaged surface 121A and, thus, heat treatment in a non-reducing atmosphere (e.g., argon alone) and may achieve good surface texture without the need for a separate hydrogen atmosphere step.

Some structural details of the glass substrate 102 pre-bonding and post-bonding will now be described. Turning first to the pre-bonding structural aspects of the glass substrate 102, the glass substrate 102 may be formed from an oxide glass or an oxide glass-ceramic. Although not required, the embodiments described herein may include an oxide glass or glass-ceramic exhibiting a strain point of less than about 1,000 degrees C. As is conventional in the glass making art, the strain point is the temperature at which the glass or glass-ceramic has a viscosity of 10^{14.6} poise (10^{13.6} Pa.s). As between oxide glasses and oxide glass-ceramics, the glasses may have the advantage of being simpler to manufacture, thus making them more widely available and less expensive.

By way of example, the glass substrate 102 may be formed from glass substrates containing alkaline-earth ions, such as, substrates made of CORNING INCORPORATED GLASS COMPOSITION NO. 1737 or CORNING INCORPORATED GLASS COMPOSITION NO. EAGLE 2000®. These glass materials have particular use in, for example, the production of liquid crystal displays.

The glass substrate may have a thickness in the range of about 0.1 mm to about 10 mm, such as in the range of about 0.5 mm to about 3 mm. For some SOG structures, insulating layers having a thickness greater than or equal to about 1 micron are desirable, e.g., to avoid parasitic capacitive effects which arise when standard SOG structures having a silicon/silicon dioxide/silicon configuration are operated at high frequencies. In the past, such thicknesses have been difficult to achieve. In accordance with the present invention, an SOG structure having an insulating layer thicker than about 1 micron is readily achieved by simply using a glass substrate 102 having a thickness that is greater than or equal to about 1 micron. A lower limit on the thickness of the glass substrate 102 may be about 1 micron.

In general, the glass substrate 102 should be thick enough to support the semiconductor layer 104 through the bonding process steps, as well as subsequent processing performed on the SOG structure to produce the TFT 100. Although there is no theoretical upper limit on the thickness of the glass substrate 102, a thickness beyond that needed for the support function or that desired for the ultimate TFT structure 100 might not be advantageous since the greater the thickness of the glass substrate 102, the more difficult it will be to accomplish at least some of the process steps in forming the TFT 100.

The oxide glass or oxide glass-ceramic substrate 102 may be silica-based. Thus, the mole percent of SiO₂ in the oxide glass or oxide glass-ceramic may be greater than 30 mole % and may be greater than 40 mole %. In the case of glass-ceramics, the crystalline phase can be mullite, cordierite, anorthite, spinel, or other crystalline phases known in the art for glass-ceramics. Non-silica-based glasses and glass-ceramics may be used in the practice of one or more embodiments of the invention, but are generally less advantageous because of their higher cost and/or inferior performance characteristics. Similarly, for some applications, e.g., for TFTs using SOG structures employing semiconductor materials that are not silicon-based, glass substrates which are not oxide based, e.g., non-oxide glasses, may be desirable, but are generally not advantageous because of their higher cost. As will be discussed in more detail below, in one or more embodiments, the glass or glass-ceramic substrate 102 is designed to match a coefficient of thermal expansion (CTE) of one or more semiconductor materials (e.g., silicon, germanium, etc.) of the layer 104 that are bonded thereto. The CTE match ensures desirable mechanical properties during heating cycles of the deposition process.

For certain applications, e.g., display applications, the glass or glass-ceramic 102 may be transparent in the visible, near UV, and/or IR wavelength ranges, e.g., the glass or glass ceramic 102 may be transparent in the 350 nm to 2 micron wavelength range.

Although the glass substrate 102 may be composed of a single glass or glass-ceramic layer, laminated structures can be used if desired. When laminated structures are used, the layer of the laminate closest to the semiconductor layer 104 may have the properties discussed herein for a glass substrate 102 composed of a single glass or glass-ceramic. Layers farther from the semiconductor layer 104 may also have those properties, but may have relaxed properties because they do not directly interact with the semiconductor layer 104. In the latter case, the glass substrate 102 is considered to have ended when the properties specified for a glass substrate 102 are no longer satisfied.

Turning now to the post-bonding aspects and characteristics of the glass substrate 102, with reference to FIG. 5, the application of the voltage potential causes alkali or alkaline earth ions in the glass substrate 102 to move away from the semiconductor/glass interface further into the glass substrate 102. More particularly, positive ions of the glass substrate 102, including substantially all modifier positive ions, migrate away from the higher voltage potential of the semiconductor/glass interface, forming: (1) a reduced positive ion concentration layer 112 in the glass substrate 102 adjacent the semiconductor/glass interface; and (2) an enhanced positive ion concentration layer 112 of the glass substrate 102 adjacent the reduced positive ion concentration layer 112. This accomplishes a number of functions: (i) an alkali or alkaline earth ion free interface (or layer) 112 is created in the glass substrate 102; (ii) an alkali or alkaline earth ion enhanced interface (or layer) 112 is created in the glass substrate 102; (iii) an oxide layer 116 is created between the exfoliation layer 122 and the glass substrate 102; and (iv) the glass substrate 102 becomes very reactive and bonds to the exfoliation layer 122 strongly with the application of heat at relatively low temperatures.

In the example illustrated in FIG. 5, the intermediate structure resulting from the electrolysis process includes, in order: a bulk glass substrate 118 (in the glass substrate 102); the enhanced alkali or alkaline earth ion layer 114 (in the glass substrate 102); the reduced alkali or alkaline earth ion layer 112 (in the glass substrate 102); the oxide layer 116; and the exfoliation layer 122. Thus, the electrolysis process transforms the interface between the exfoliation layer 122 and the glass substrate 102 into an “interface region” comprising layer 112 (which is a positive ion depletion region) and layer 114 (which is a positive ion enhancement region). The interface region may also include one or more positive ion pile-up regions in the vicinity of the distal edge of the positive ion depletion layer 112.

The positive ion enhancement layer 114 is of enhanced oxygen concentration and has a thickness. This thickness may be defined in terms of a reference concentration for oxygen at a reference surface (not shown) above the glass substrate 102. The reference surface is substantially parallel to the bonding surface between the glass substrate 102 and the exfoliation layer 120 and is separated from that surface by a distance. Using the reference surface, the thickness of the positive ion enhancement layer 114 will typically satisfy the relationship:

T≦200 nm,

where T is the distance between bonding surface and a surface which is: (i) substantially parallel to bonding surface, and (ii) is the surface farthest from bonding surface for which the following relationship is satisfied:

CO(x)-CO/Ref≧50 percent, 0≦x≦T,

where CO(x) is the concentration of oxygen as a function of distance x from the bonding surface, CO/Ref is the concentration of oxygen at the above reference surface, and CO(x) and CO/Ref are in atomic percent.

Typically, T will be substantially smaller than 200 nanometers, e.g., on the order of about 50 to about 100 nanometers. It should be noted that CO/Ref will typically be zero, so that the above relationship will in most cases reduce to:

CO(x)≧50 percent, 0≦x≦T.

In connection with the positive ion depletion layer 112, the oxide glass or oxide glass-ceramic substrate 102 preferably comprises at least some positive ions that move in the direction of the applied electric field, i.e., away from the bonding surface and into the layer 114 of the glass substrate 102. Alkali ions, e.g., Li⁺¹, Na⁺¹, and/or K⁺¹ ions, are suitable positive ions for this purpose because they generally have higher mobilities than other types of positive ions typically incorporated in oxide glasses and oxide glass-ceramics, e.g., alkaline-earth ions. However, oxide glasses and oxide glass-ceramics having positive ions other than alkali ions, e.g., oxide glasses and oxide glass-ceramics having only alkaline-earth ions, can be used in the practice of the invention. The concentration of the alkali and alkaline-earth ions can vary over a wide range, representative concentrations being between 0.1 and 40 wt. % on an oxide basis. Preferred alkali and alkaline-earth ion concentrations are 0.1 to 10 wt. % on an oxide basis in the case of alkali ions, and 0-25 wt. % on an oxide basis in the case of alkaline-earth ions.

The electric field applied in the electrolysis process moves the positive ions (cations) further into the glass substrate 102 forming the positive ion depletion layer 108. The formation of the positive ion depletion layer 112 is especially desirable when the oxide glass or oxide glass-ceramic contains alkali ions, since such ions are known to interfere with the operation of semiconductor devices. Alkaline-earth ions, e.g., Mg⁺², Ca⁺², Sr⁺², and/or Ba⁺², can also interfere with the operation of semiconductor devices and thus the depletion region also preferably has reduced concentrations of these ions.

It has been found that the positive ion depletion layer 112 once formed is stable over time even if the SOG structure 100 is heated to an elevated temperature comparable to, or even to some extent higher than, that used in the electrolysis process. Having been formed at an elevated temperature, the positive ion depletion layer 112 is especially stable at the normal operating and formation temperatures of SOG structures. These considerations ensure that alkali and alkaline-earth ions will not diffuse back from the oxide glass or oxide glass-ceramic 102 into any semiconductor material that may be later applied to the glass substrate 102 directly or to the oxide layer 116, during use or further device processing, which is an important benefit derived from using an electric field as part of the electrolysis process.

The operating parameters needed to achieve the positive ion depletion layer 112 of a desired width and a desired reduced positive ion concentration for all of the positive ions of concern can be readily determined by persons skilled in the art from the present disclosure. When present, the positive ion depletion layer 112 is a characteristic feature of an SOG structure produced in accordance with one or more embodiments of the present invention.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of re-using a semiconductor donor wafer in a semiconductor-on-insulator (SOI) fabrication process, the method comprising:
(a) subjecting a first implantation surface of a donor semiconductor wafer to an ion implantation process to create a first exfoliation layer of the donor semiconductor wafer;
(b) bonding the first implantation surface of the first exfoliation layer to a first insulator substrate;
(c) separating the first exfoliation layer from the donor semiconductor wafer, thereby exposing a first cleaved surface of the donor semiconductor wafer, the first cleaved surface having a first damage thickness; and
(d) subjecting the first cleaved surface of the donor semiconductor wafer to one or more elevated temperatures over time to reduce the first damage thickness to a sufficient level to produce a second implantation surface.

2. The method of claim 1, further comprising repeating steps (a)-(d) to produce further exfoliation layers for further SOI structures.

3. The method of claim 1, further comprising touch polishing the first cleaved surface of the donor semiconductor wafer to remove about 10-100 nm of material, thereby reducing a surface roughness of the first cleaved surface.

4. The method of claim 1, wherein the one or more elevated temperatures includes at least one temperature within the range of about 700 degrees C to about 1200 degrees C.

5. The method of claim 4, wherein the at least one temperature is about 1000-1100 degrees C.

6. The method of claim 1, wherein the time is between about 1 to about 8 hours.

7. The method of claim 6, wherein the time is about 4 hours.

8. The method of claim 1, wherein the step of subjecting the first cleaved surface of the donor semiconductor wafer to one or more elevated temperatures over time is conducted in an inert atmosphere.

9. The method of claim 8, wherein the atmosphere includes argon.

10. The method of claim 1, wherein the step of subjecting the first cleaved surface of the donor semiconductor wafer to one or more elevated temperatures over time is conducted in a reducing atmosphere.

11. The method of claim 10, wherein the atmosphere includes hydrogen.

12. The method of claim 10, wherein the atmosphere includes a mixture of an inert gas and hydrogen.

13. The method of claim 10, wherein the inert gas is argon.

14. The method of claim 1, wherein the donor semiconductor wafer is a single crystal semiconductor wafer.

15. The method of claim 14, wherein the donor semiconductor wafer is taken from the group consisting of: silicon (Si), germanium-doped silicon (SiGe), silicon carbide (SiC), germanium (Ge), gallium arsenide (GaAs), GaP, and InP.

16. The method of claim 1, wherein the insulator substrate is a glass or glass ceramic substrate.

17. The method of claim 16, wherein the step of bonding includes:
heating at least one of the glass substrate and the donor semiconductor wafer;
bringing the glass substrate into direct or indirect contact with the donor semiconductor wafer through the exfoliation layer; and
applying a voltage potential across the glass substrate and the donor semiconductor wafer to induce the bond.

18. The method of claim 17, further comprising maintaining the contact, heat, and voltage such that: (i) an oxide layer forms on the substrate between the donor semiconductor wafer and the substrate; and (ii) positive ions of the substrate, including substantially all modifier positive ions, migrate away from the higher voltage potential of the donor semiconductor wafer, forming: (1) a reduced positive ion concentration layer in the substrate adjacent the donor semiconductor wafer; and (2) an enhanced positive ion concentration layer of the substrate adjacent the reduced positive ion concentration layer.

19. A semiconductor on glass (SOG) structure, comprising:
a glass or glass ceramic substrate; and
a single crystal semiconductor layer having a bonding surface bonded to the glass or glass ceramic substrate via electrolysis, wherein the single crystal semiconductor layer is formed using steps, comprising:
(a) subjecting a first cleaved surface of a donor semiconductor wafer to one or more elevated temperatures over time to reduce a first damage thickness thereof to a sufficient level to produce a first implantation surface;
(b) subjecting a first implantation surface of the donor semiconductor wafer to an ion implantation process to create a first exfoliation layer of the donor semiconductor wafer;
(c) bonding the first implantation surface of the first exfoliation layer to the glass or glass ceramic substrate; and
(d) separating the first exfoliation layer from the donor semiconductor wafer, thereby exposing a second cleaved surface of the donor semiconductor wafer, the second cleaved surface having a second damage thickness.

20. The SOG of claim 19, wherein the single crystal semiconductor layer is taken from the group consisting of: silicon (Si), germanium-doped silicon (SiGe), silicon carbide (SiC), germanium (Ge), gallium arsenide (GaAs), GaP, and InP.

21. The SOG of claim 19, wherein:
the glass or glass ceramic substrate includes, in order, a bulk layer, an enhanced positive ion concentration layer, a reduced positive ion concentration layer, where the enhanced positive ion concentration layer contains substantially all modifier positive ions from the reduced positive ion concentration layer as a result of migration; and
a conductive or semiconductive oxide layer is located between the reduced positive ion concentration layer of the substrate and the single crystal semiconductor layer.
